(19) United States
(12) Patent Application Publication
(10) Pub. No.: US 2002/0009861 A1
(43) Pub. Date: Jan. 24, 2002

(54) METHOD AND APPARATUS FOR THE FORMATION OF DIELECTRIC LAYERS

(76) Inventors: PRAVIN K. NARWANKAR, SUNNYVALE, CA (US); TURGUT SAHIN, CUPERTINO, CA (US); RANDALL S. URDAHL, PALO ALTO, CA (US); ANKINEEDU VELAGA, CUPERTINO, CA (US); PATRICIA LIU, SARATOGA, CA (US)

Correspondence Address: PATENT COUNSEL MS 2061, LEGAL AFFAIRS DEPT, APPLIED MATERIALS INC, BOX 450A, SANTA CLARA, CA, 95052

(21) Appl. No.: 09/096,858

(22) Filed: Jun. 12, 1998

(51) Int. Cl. H01L 21/76; H01L 21/31; H01L 21/469

(52) U.S. Cl. 438/404

(57) ABSTRACT

A method and apparatus for forming and annealing a dielectric layer. According to the present invention an active atomic species is generated in a first chamber. A dielectric layer formed on a substrate is then exposed to the active atomic species in a second chamber, wherein the second chamber is remote from the first chamber.

### BACKGROUND OF THE INVENTION

1. Field of the Invention

The present invention relates to the field of dielectric formation and more specifically to a method and apparatus for annealing a dielectric film.

2. Discussion of Related Art

Integrated circuits are made up of literally millions of active and passive devices such as transistors, capacitors and resistors. In order to provide more computational power and/or more storage capability in an integrated circuit, device features are reduced or scaled down in order to provide higher packing density of devices. An important feature to enable scaling of devices is the ability to form high quality, high dielectric constant films for capacitor and gate dielectrics.

High dielectric constant films are generally ceramic films (i.e., metal-oxides) such as tantalum pentaoxide and titanium oxide. When these films are deposited they tend to have vacancies at the anionic (oxygen) sites in the lattice. Presently these vacancies are filled by annealing the film in a gas mixture which can provide an active species to occupy the lattice vacancies. For example, furnace anneals and rapid thermal oxidation (RNO) are presently used to anneal dielectric films. In such processes a substrate is placed in a furnace or a chamber of a rapid thermal apparatus and heated to a high temperature, greater than 800° C., while an anneal gas such as O₂ or N₂ is fed directly into the furnace or chamber, respectively, where the substrate is located. These processes must be performed at very high temperatures, greater than 800° C., in order to generate the active species from the anneal gas.

A problem with utilizing such high anneal temperatures is that dielectric films such as tantalum pentaoxide crystallize when exposed to high temperatures which can lead to high leakage currents. Additionally high anneal temperatures can cause other ions to diffuse into the film, especially at the interfaces of the devices, and cause poor electrical performance. Still further, many modern high density processes require a reduced thermal budget in order to prevent or minimize dopant diffusion or redistribution in a device. Still further some processes utilize materials with low melting points which preclude subsequent use of high temperature processing.

Thus, what is desired is a method and apparatus for forming a high quality, high dielectric constant dielectric film at a low temperature.

### SUMMARY OF THE INVENTION

A method and apparatus for annealing a dielectric layer is described. According to the present invention active atomic species are generated in a first chamber. A dielectric layer formed on a substrate is then exposed to the active atomic species in a second chamber which is remote from the first chamber.

### BRIEF DESCRIPTION OF THE DRAWINGS

FIG. 1 is a flow chart which illustrates a process of forming a dielectric layer in accordance with the present invention.

FIG. 2a is an illustration of a cross-section view of a substrate including a interlayer dielectric and a bottom electrode.

FIG. 2b is an illustration of a cross-sectional view showing the passivation of the substrate of FIG. 2a.

FIG. 2c is an illustration of a cross-sectional view showing the formation of a dielectric film on the substrate of FIG. 2b.

FIG. 2d is an illustration of a cross-sectional view showing the formation of an annealed dielectric film on the substrate of FIG. 2b.

FIG. 2e is an illustration of a cross-sectional view showing the formation of a top electrode on the substrate of FIG. 2d.

FIG. 3a is an illustration of an apparatus which may be utilized to anneal a dielectric layer in accordance with the present invention.

FIG. 3b is an illustration of a chamber which may be used in the apparatus of FIG. 3a.

FIG. 4 is a graph which illustrates how leakage current varies for different electrode voltages for a capacitor formed with a unannealed tantalum pentaoxide dielectric layer and for a capacitor formed with a tantalum pentaoxide dielectric layer annealed with remotely generated active atomic species.

FIG. 5a is an illustration of a cross-section view of a substrate having been passivated with active atomic species.

FIG. 5b is an illustration of the cross-sectional view as showing the formation of the dielectric film on the substrate of FIG. 5a.

FIG. 5c is an illustration of cross-sectional view showing the formation of an annealed dielectric on the substrate of FIG. 5a.

FIG. 5d is an illustration of the cross-sectional view showing the formation of a gate electrode and source/drain regions on the substrate of FIG. 5c.

### DETAILED DESCRIPTION OF THE PRESENT INVENTION

The present invention describes a novel method and apparatus for annealing a dielectric film. In the following description numerous specific details such as specific equipment configurations, and process parameters are set forth in order to provide a thorough understanding of the present invention. One skilled in the art will appreciate the ability to use alternative configurations and process details to the disclosed specifics without departing from the scope of the present invention. In other instances, well known semiconductor processing equipment and methodology have not been described in detail in order to not unnecessarily obscure the present invention.

The present invention describes a novel method and apparatus for passivating and/or annealing films. According to the present invention highly reactive atomic species are used to nitridate, passivate, deposit and anneal films. The highly reactive atomic species are formed in a plasma created by exposing an anneal gas such as O₂ and N₂O, and N₂ to microwaves. The plasma creates electrically neutral highly energized atoms from the molecular anneal gas. The plasma used to generate the active atomic species is created in a cavity or chamber which is separate (remote) from the chamber in which the substrate to be annealed or passivated is located. Because the atomic species are in a highly energized state when they enter the anneal chamber, they readily react with films and substrates, and so do not require high substrate temperatures to initiate reaction. Because the present invention utilizes remotely generated highly reactive atomic species low substrate temperatures, less than or equal to 400° C., can be used nitridating, passivating, depositing, and annealing films and substrate. The low temperature processes of the present invention can substantially reduce the thermal budget necessary to manufacturer integrated circuits. Additionally because the active atomic species are remotely generated, the substrate to be annealed or passivated is not exposed to the harmful plasma used for generating the active atomic species.

In one embodiment of the present invention remotely generated active atomic species are used to passivate a silicon substrate prior to the formation of a gate dielectric layer or are used to passivate a capacitor electrode prior to the formation of a capacitor dielectric layer thereon. It is to be appreciated that as gate and capacitor dielectric film thicknesses shrink, to enable the fabrication of high density integrated circuits, the atomic level interfaces between the substrate and dielectric are becoming increasingly more important for device reliability and performance. By passivating a substrate with remotely generated active atomic species one can improve the atomic level interfaces between the substrate and the dielectric film and thereby improve device reliability and performance.

In another embodiment of the present invention, remotely generated active atomic species are used to anneal an active dielectric film, such as a gate dielectric or a capacitor dielectric. According to this embodiment of the present invention a dielectric film is deposited over substrate. The dielectric film is then exposed to remotely generated active atomic species, such as reactive oxygen atoms or reactive nitrogen atoms. The highly energized atomic species readily react with the dielectric film to fill vacancies in the lattice which left unfilled can lead to high leakage currents and poor device performance. The remotely generated active atomic species can be used to anneal a wide range of dielectrics such as but not limited to silicon oxides, such as silicon dioxide and silicon oxynitride, transition-metal dielectrics such as tantalum pentaoxide (Ta₂O₅), titanium oxide (TiO₂) and titanium doped tanatalum pentaoxide, as well as ferroelectric and piezoelectric dielectrics such as BST, and PZT. Additionally, active atomic species, such as reactive nitrogen atoms can be used to anneal dielectric barrier layers, such as silicon nitride, to improve their barrier qualities.

In an embodiment of the present invention the remotely generated active atomic species are provided into the deposition chamber while the dielectric film is being deposited. In this way the dielectric film is annealed as it is deposited thereby eliminating the need for a separate anneal step.

As such remotely generated active atomic species can be used in all phases of dielectric film formation including substrate passivation prior to dielectric layer deposition, annealing during dielectric deposition and annealing after dielectric deposition. In this way high quality, high performance capacitor and gate dielectrics as well as barrier layers can be fabricated.

In one specific embodiment of the present invention, remotely generated reactive oxygen atoms are used to anneal a transition-metal dielectric used as a capacitor dielectric in a dynamic random access memory (DRAM). In this embodiment of the present invention a transition-metal dielectric film is formed by chemical vapor deposition (CVD) over a bottom electrode of a DRAM cell. The transition-metal film is then annealed at a temperature less than 400° C. with reactive oxygen atoms formed in a chamber separate from the anneal chamber. The remotely generated reactive oxygen atoms readily react with the deposited transition-metal film and satisfy open sites in the film. Additionally, the reactive oxygen atoms remove carbon contaminates by chemically reacting with carbon and forming carbon dioxide (CO₂) vapor which is then exhausted from the chamber. By annealing the dielectric film with remotely generated reactive oxygen atoms, the leakage current of the film can be substantially reduced. A top capacitor electrode can then be formed on the high quality high dielectric constant film thereby improving the performance and reliability of the fabricated cell.

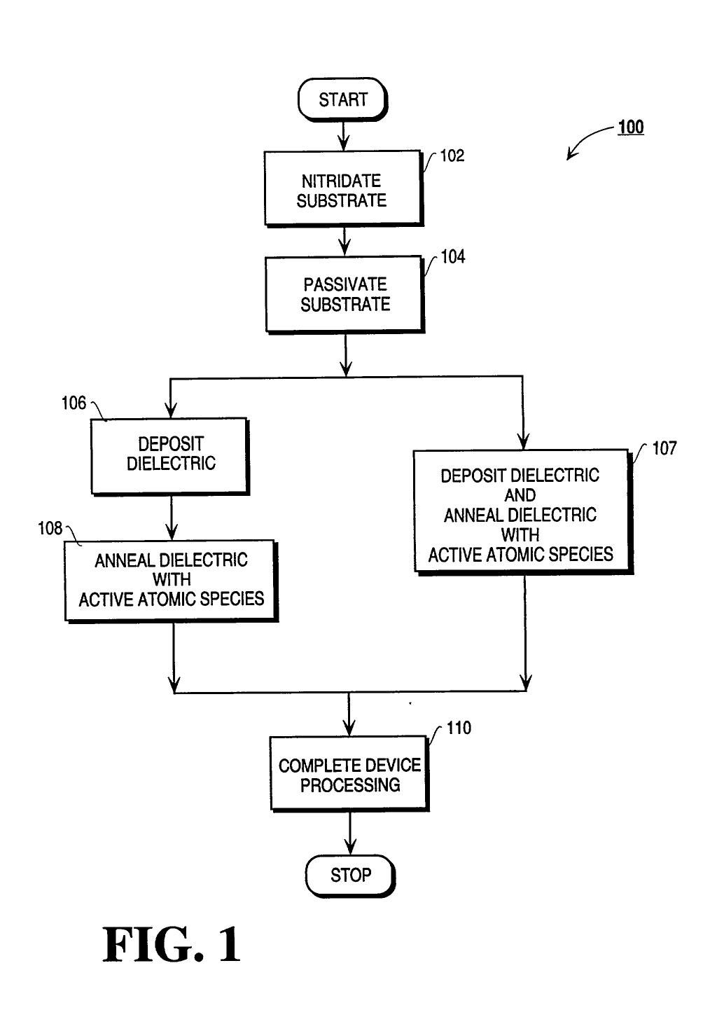

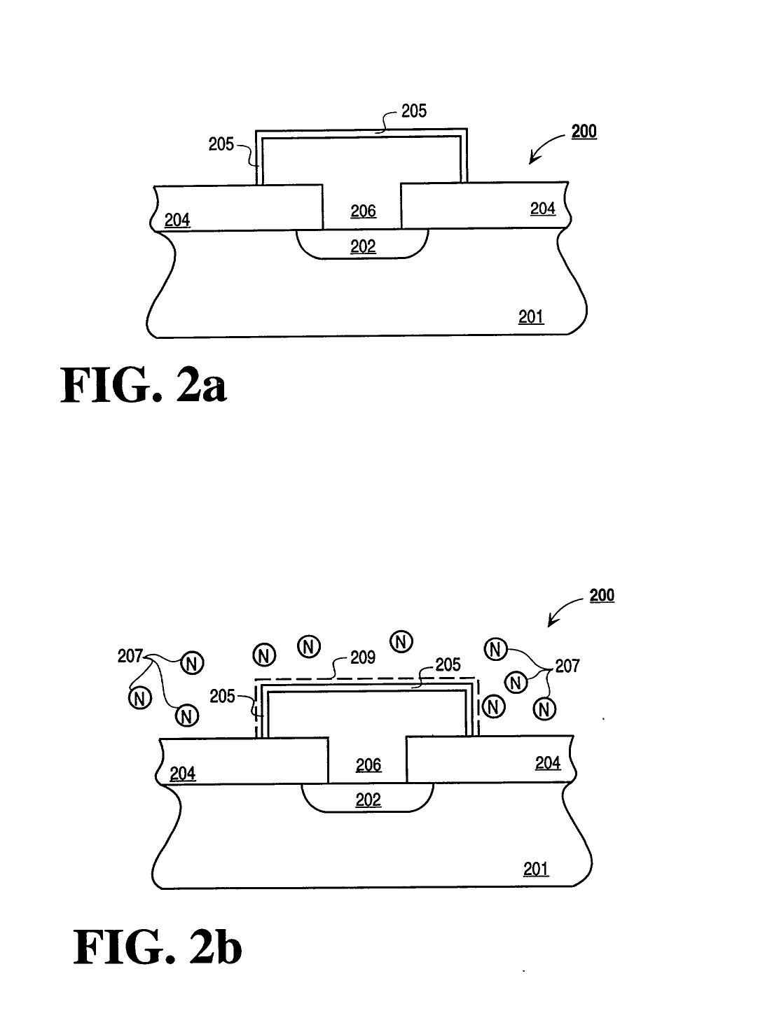

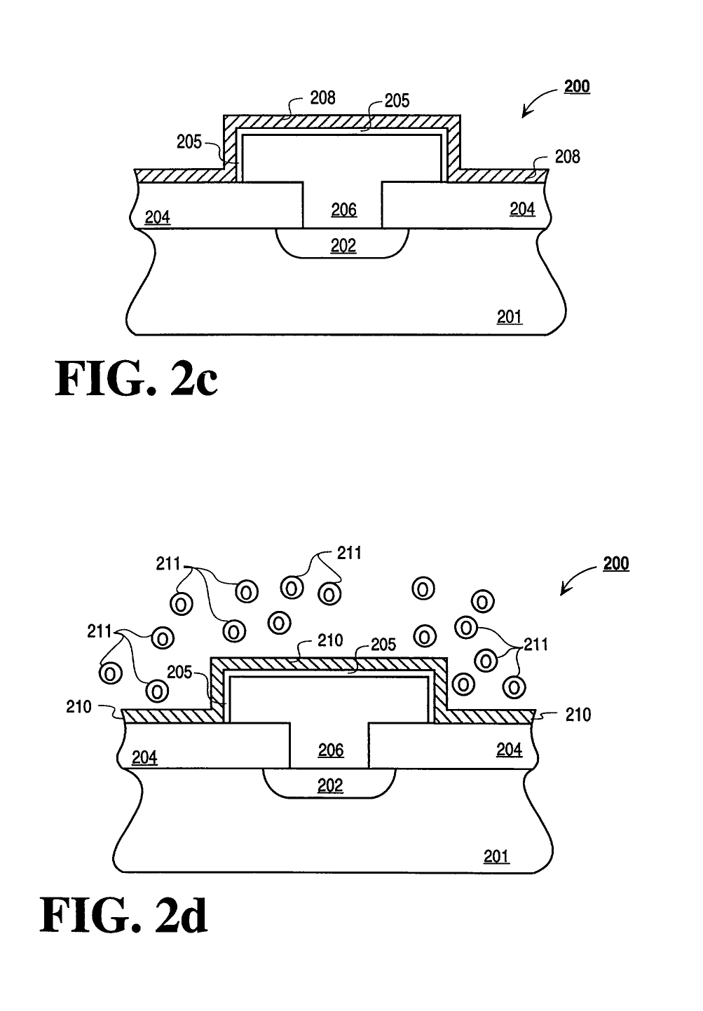

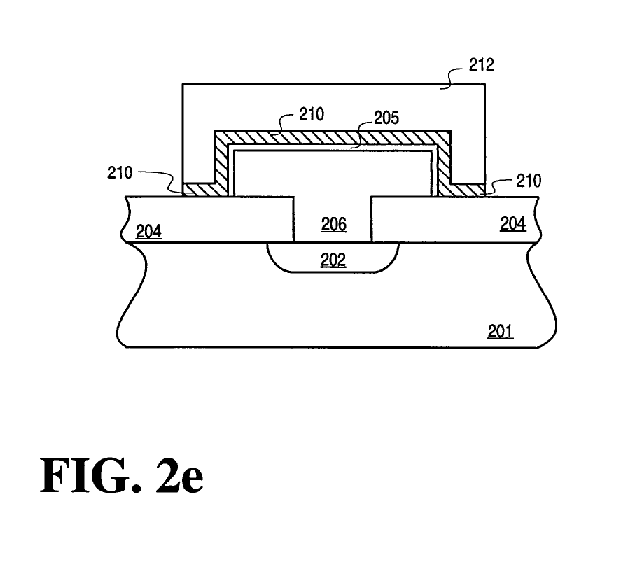

A method of forming and annealing a dielectric layer in accordance with the present invention will be described in reference to FIG. 1 and FIGS. 2a-2e. FIG. 1 illustrates a flow chart which depictsasingle process which utilizes the different nitridation, passivation, deposition, and anneal processes of the present invention. FIGS. 2a-2e illustrate an embodiment of the present invention where the processes of the present invention are used to form a capacitor of a DRAM cell. It is to be appreciated that these specific details are only illustrative of an embodiment of the present invention and are not to be taken as limiting to the present invention. Additionally, it is to be appreciated that the nitridation, passivation, deposition and anneal processes of the present invention need not all be used in a single process and can be used independently or in different combination with one another to form a wide variety of different integrated circuits.

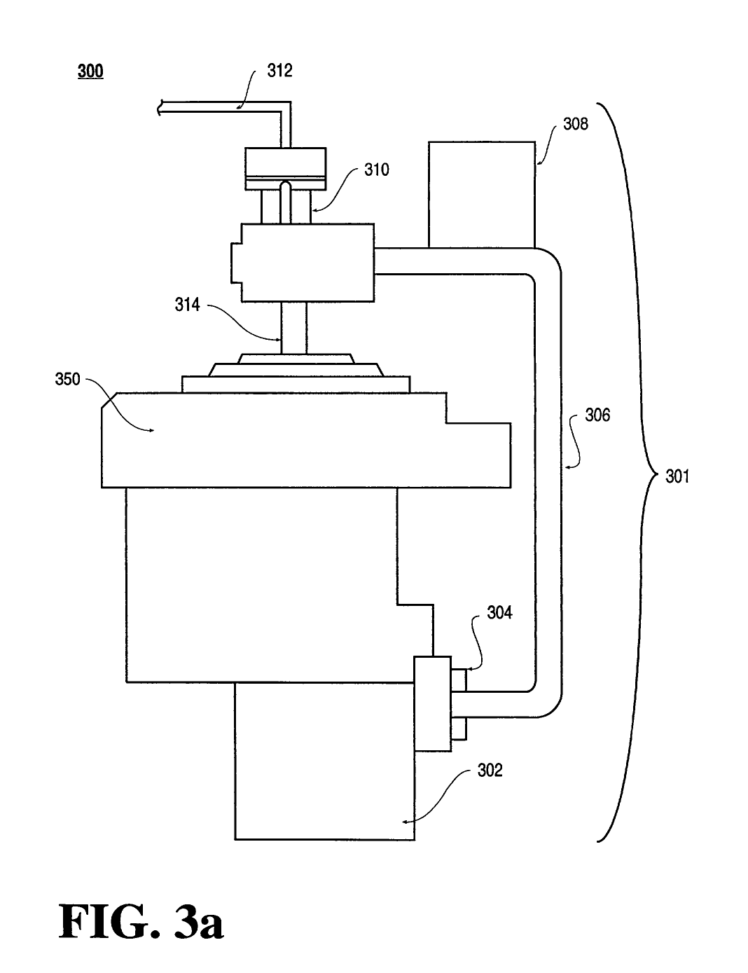

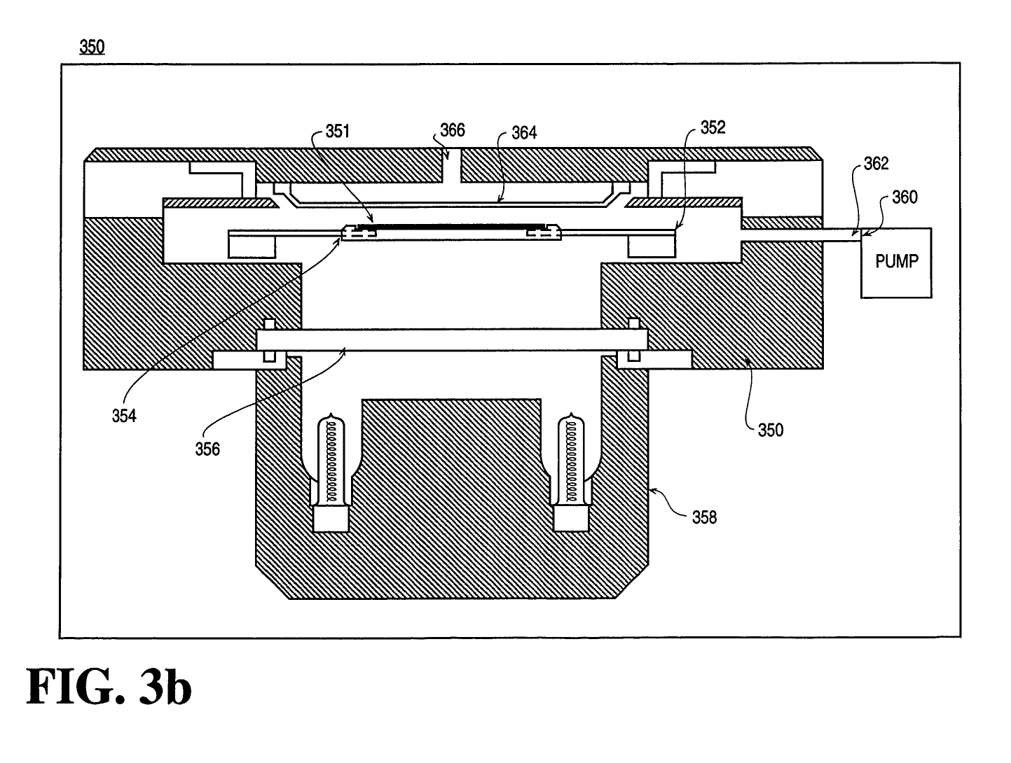

An example of an apparatus 300 which can be used to provide active atomics species for the anneal and/or passivation steps of the present invention is illustrated in FIGS. 3a and 3b. An example of a commercially available apparatus which can be used to provide active atomic species is the Applied Materials Centura Advanced Strip Passivation Plus (ASP) chamber. Apparatus 300 includes a remote plasma generator 301 which generates and provides active atomic species to a process chamber 350 in which the substrate to be passivated or annealed is located. Remote plasma generator 301 includes a magnatron 302 which generates microwaves with a microwave source. Magnatron 302 can preferably generate up to 10,000 watts of 2.5 Ghz microwave energy. It is to be noted that the amount of power required is dependent (proportional) to the size of anneal chamber 350. For an anneal chamber used to process 300 mm wafers, 10,000 watts of power should be sufficient. Although a microwave source is used to generate a plasma in apparatus 300, other energy sources such as radio frequency (RF) may be used.

Magnatron 302 is coupled to an isolator and dummy load 304 which is provided for impedance matching. The dummy load absorbs the reflected power so no reflective power goes to the magnatron head. Isolator and dummy load 304 is coupled by a wave guide 306, which transmits microwave energy to an autotuner 308. Autotuner 308 consist of an impedance matching head and a separate detector module that uses three stepper motor driven impedance matching stubs to reduce the reflective power of the microwave energy directed to the power source. Autotuner 308 focuses the microwave energy into the center of a microwave applicator cavity (or chamber) 310 so that energy is absorbed by annealed gas fed into the applicator cavity 310. Although an autotuner is preferred a manual tuner may be employed.

Applicator 310 uses microwave energy received from magnatron 302 to create a plasma from the anneal gas as it flows down through a quartz plasma tube located inside applicator 310. A source 312, such as a tank, of a anneal gas such as but not limited to O₂,N₂O, and N₂ used for generating the active atomic species is coupled to microwave applicator 310. Additionally, a source of an inert gas such as argon (Ar) or helium (He) can also be coupled to applicator 310. A prefire mercury lamp can be used to radiate ultraviolet light into the plasma tube to partially ionize the process gases and thereby make it easier for the microwave energy to ignite the plasma.

The microwave energy from magnetron 302 converts the anneal gas into a plasma which consist of essentially three components; ionized or charged atoms (radicals), activated (reactive) atomic species, and nondissociated anneal gas. For example when O₂ is the anneal gas, microwave energy disassociates the O₂ gas into oxygen radicals, reactive oxygen atoms, and some anneal gas remains as O₂ molecules. When N₂ is the anneal gas, microwaves disassociate the N₂ gas into nitrogen radicals, reactive nitrogen atoms, and some anneal gas remains as N₂ molecules. Reactive atomic species such as reactive oxygen atoms or reactive nitrogen atoms are not charged or ionized but are highly energized atoms. Because the reactive atomic species are highly energized they are in a highly reactive state so they readily react with dielectric films to fill vacancies therein or to passivate films or substrates. Because the atomic species are highly energized when they enter anneal chamber 350, high temperatures are not necessary in chamber 350 to activate the anneal gas.

Applicator 310 is bolted to the lid of chamber 350. The concentrated plasma mixture flows downstream through conduit 314 to chamber 350. As a plasma flows through the conduit 314 the ionized atoms become electrically neutral before reaching chamber 350 and become highly reactive atomic species. Thus, only electrically neutral, highly reactive atoms flow into chamber 350. Although the process gas at this point is highly reactive, the mixture is no longer electrically damaging to the substrate or electrical devices such as transistors formed therein. Because the active atomic species are generated at location (chamber 310) which is separate or remote from the chamber 350 in which the substrate to be annealed is located, the active atomic species are said to be “remotely generated”.

Chamber of 350 of apparatus 300, as shown in FIG. 3b, includes a wafer support 352 for supporting a wafer or substrate 351 face up in chamber 350. Wafer support 352 can include an aluminum chuck 354. Chamber 350 includes a quartz window 356 through which infrared radiation from a plurality (14) of quartz tungsten halogen lamp 358 is transmitted. During processing, the lamps mounted directly below the process chamber radiantly heat the chuck which in turn heats the wafer by conduction. A closed loop temperature control system senses the temperature of the substrate or wafer using a thermocouple mounted in the chuck. The temperature control system regulates the temperature of the wafer by varying the intensity of lamps 358. Although lamps are preferably used as the heat source for heating the wafer, other heat sources, such as resistive heaters, can be used. A vacuum source 360, such as the pump, is coupled to an exhaust outlet 362 and controls the chamber pressure and removes gas by products. A shower head or gas distribution plate 364 is mounted directly above the wafer. Shower head 364 consist of three quartz plates having a plurality of holes formed therein to evenly distribute the active atomic species over the wafer as they flow through gas inlet 366.

In one embodiment of the present invention, chamber 350 is also configured to receive deposition gases used to deposit a film by chemical vapor deposition (CVD). In this way, a dielectric film can be annealed in the same chamber as used to deposit the film, or the dielectric film can be annealed as it is deposited. Additionally, chamber 350 can be a thermal reactor such as the Applied Material's Poly Centura single wafer chemical vapor deposition reactor or the Applied Material's RTP Centura with the honeycomb source, each configured to receive active atomic species from remote plasma generator 301. In one embodiment of the present invention apparatus 300 is part of a cluster tool which includes among other chambers, a chemical vapor deposition (CVD) chamber, a load lock, and a transfer chamber with a robot arm. Configuring the various chambers around a transfer chamber in the form of a cluster tool enables wafers or substrates to be transferred between the various chambers of the cluster tool without being exposed to an oxygen ambient.

The nitridation, passivation, deposition and anneal steps of the present invention occur on a substrate. For the purpose of the present invention a substrate is the material on which dielectric films are deposited and annealed in accordance with the present invention. The substrate can be a substrate used in the manufacturing of semiconductor products such as silicon substrates and gallium arsenide substrates and can be other substrates used for other purposes such as glass substrates used for the production of flat panel displays.

In one embodiment of the present invention, the substrate is a substrate used in the fabrication of a dynamic random access memory (DRAM) cells such as substrate 200 shown in FIG. 2a. Substrate 200 includes well known silicon epitaxial substrate 201 having a doped region 202 and a patterned interlayer dielectric 204. A bottom capacitor electrode 206 is formed in contact with the diffusion region 202 and over ILD 204. Bottom capacitor electrode 206 can be formed by any well known technique such as by blanket depositing a polysilicon layer by chemical vapor deposition (CVD) utilizing a reactive gas comprising silane (SiH₄) and H₂ and then patterning the blanket deposited material into an electrode with well known photolithography and etching techniques. If bottom electrode 206 is a polysilicon electrode it will typically be doped to a density between 2-5×10²⁰ atoms/cm³. Bottom electrode 206 can also be other types of capacitor electrodes such as but not limited to hemispherical grained polysilicon (HSG) or “rough poly” electrodes and metal electrodes such as titanium nitride (TiN) and tugsten (W) electrodes. In still other cases, the monocyrstalline silicon substrate 201 can act as the bottom electrode.

The first step, in one embodiment of the present invention, as set forth in block 102 of flow chart 100, is to nitridate substrate 200 to form a thin, between 10-25 Å, silicon nitride barrier layer 205 on bottom electrode 206 as shown in FIG. 2a. Nitridating bottom electrode 206 is desirable when bottom electrode 206 is a silicon electrode. Silicon nitride film 205 forms an oxidation prevention barrier layer for bottom electrode 206. In this way, oxygen can not penetrate grain boundaries of polysilicon electrode 206 and form oxides therein which can lead to a decrease in the effective dielectric constant of a capacitor dielectric and to an increase in electrode resistance. Additionally, in well known capacitor structures where the monocrystalline silicon substrate 201 acts as the bottom electrode, nitridating substrate 201 is desirable.

A thin silicon nitride layer can be formed by nitridating substrate 200 by exposing substrate 200 to remotely generated reactive nitrogen atoms in anneal chamber 350 while substrate 200 is heated to a temperature between 700-900° C. and chamber 350 maintain at a pressure between 0.5 torr-2 torr. Reactive nitrogen atoms can be formed by flowing between 0.5 to 2 SLM of N₂or ammonia (NH₃) into cavity 310 and applying a power between 1400-5000watts to magnatron 302 to create plasma from the N₂ or NH₃ gas in cavity 310. The nitradation process forms silicon nitride only on those locations where silicon is available to react with the reactive nitrogen atoms, such as polysilicon electrode 206 and not on those areas where no silicon is available for reaction such as ILD 206. A suitable silicon nitride layer 205 can be formed by nitridating substrate 200 with remotely generated reactive nitrogen atoms for between 30-120 seconds. Alternatively, a thin silicon nitride layer 205 can be formed by other well known techniques such as by thermal nitridation in a LPCVD batch type furnace.

Next, as set forth in step 104 of flow chart 100, in an embodiment of the present invention, substrate 200 is passivated with remotely generated reactive nitrogen atoms, as shown in FIG. 2b, to cure defects in silicon nitride barrier layer 205. Silicon nitride barrier layer 205 can be passivated by placing substrate 200 on chuck 354 in chamber 350 and heating substrate 200 to a temperature between 300-500 while an N₂ anneal gas is fed into cavity 310 at a rate of between 0.5-2 SLM and a power of between 1400-5000 watts is provided to magnatron 302. Microwaves from magnatron 302 create a plasma in cavity 310 from the N₂ process gas. Highly reactive electrically neutral nitrogen atoms 207 then flow through conduit 314 into chamber 350 where they passivate 209 substrate 200. Exposing substrate 200 to active nitrogen atoms 207 can be used to stuff the capacitor electrode 206 with nitrogen atoms and thereby prevent subsequent oxidation of the capacitor electrode. Silicon nitride layer 205 can be sufficiently passivated by exposing substrate 200 to remotely generated reactive nitrogen atoms for between 30-120 seconds. Alternatively, silicon nitride barrier layer 205 can be passivated by subsituting forming gas (3-10% H₂ and 97-90% N₂) for the N₂ anneal gas. The addition of hydrogen (H₂) helps to cure defects and to remove contaminates.

Next, as set forth in block 106, a dielectric film is formed over substrate 200. In one embodiment of the present invention a high dielectric constant dielectric film 208 is blanket deposited over ILD 204 and bottom electrode 206 of substrate 200 as shown in FIG. 2c. In an embodiment of the present invention the dielectric film is a transition metal dielectric film such as, but not limited to, tantalum pentaoxide (Ta₂O₅) and titanium oxide (TiO₂). In another embodiment dielectric layer 208 is a tantalum pentaoxide film doped with titanium. Additionally dielectric layer 208 can be a composite dielectric film comprising a stack of different dielectric films such as a Ta₂O₅/TiO₂/Ta₂O₅stacked dielectric film. Additionally, dielectric layer 208 can be a piezoelectric dielectric such as Barium Strontium Titanate (BST) and Lead Zerconium Titanate (PZT) or a ferroelectric.

In other embodiments of the present invention dielectric layer 208 can be a silicon-oxide dielectric such as silicon dioxide and silicon oxynitride and composite dielectric stacks of silicon-oxide and silicon nitride film such as well known ONO and NO and nitrided oxides. The fabrication of such oxides are well known and can be used in the fabrication of gate dielectric layers and capacitor dielectrics. For example a low temperature silicon dioxide film can be formed by chemical vapor deposition utilizing a silicon source, such as TEOS, and an oxygen source, such as O₂.

In order to form a dielectric layer 208 onto substrate 200, the substrate can be placed into a thermal process chamber such as the chamber of an Applied Materials CVD single wafer reactor. Alternatively, substrate 201 can be placed or left in anneal chamber 350 configured to receive deposition gases. The substrate is then heated to a desired deposition temperature while the pressure within the chamber is pumped down (reduced) to a desired deposition pressure. Deposition gases are then fed into the chamber and a dielectric layer formed therefrom.

To blanket deposit a tantalum pentaoxide (Ta₂O₅) dielectric film by thermal chemical vapor deposition a deposition gas mix comprising, a source of tantalum, such as but not limited to, TAETO [Ta (OC₂H₅)₅] and TAT-DMAE [Ta (OC₂H₅)₄ (OCHCH₂N(CH₃)₂], and source of oxygen such as O₂ or N₂O can be fed into a deposition chamber while the substrate is heated to a deposition temperature of between 300-500° C. and the chamber maintained at a deposition pressure of between 0.5-10 Torr. The flow of deposition gas over the heated substrate results in thermal decomposition of the metal organic Ta-containing precursor an subsequent deposition of a tantalum pentaoxide film. In one embodiment TAETO or TAT-DMAE is fed into the chamber at a rate of between 10-50 milligrams per minute while O₂ or N₂O is fed into the chamber at a rate of 0.3-1.0 SLM. TAETO and TAT-DMAE can be provided by direct liquid injection or vaporized with a bubbler prior to entering the deposition chamber. A carrier gas, such as N₂,H₂ and He, at a rate of between 0.5-2.0 SLM can be used to transport the vaporized TAETO or TAT-DMAE liquid into the deposition chamber. Deposition is continued until a dielectric film 508 of a desired thickness is formed. A tantalum pentaoxide (Ta₂O₅) dielectric film having a thickness between 50-200 Å provides a suitable capacitor dielectric.

It has been found that the use of nitrous oxide (N₂O) as the oxidizer (source of oxygen), as opposed to oxygen gas O₂ improves the electrical properties of the deposited tantalum pentaoxide (Ta₂O₅) dielectric film during deposition. The use of N₂O, as opposed to O₂,has been found to reduce the leakage current and enhance the capacitance of fabricated capacitors. The inclusion of N₂O as an oxidizer aids in the removal of carbon from the film during growth which helps to improve the quality of the film.

In an embodiment of the present invention dielectric layer 208 is a tantalum pentaoxide (Ta₂O₅) film doped with titanium (Ti). A tantalum pentaoxide film doped with titanium can be formed by thermal chemical vapor deposition by providing a source of titanium, such as but not limited to TIPT (C₁₂H₂₆O₄Ti), into the process chamber while forming a tantalum pentaoxide film as described above. TIPT diluted by approximately 50% with a suitable solvent such as isopropyl alcohol (IPA) can be fed into the process chamber by direct liquid injection or through the use of a bubbler and carrier gas such as N₂. A TIPT diluted flow rate of between 5-20 mg/minute can be used to produce a tantalum pentaoxide film having a titanium doping density of between 5-20 atomic percent and a dielectric constant between 20-40. The precise Ti doping density can be controlled by varying the tantalum source flow rate relative to the titanium source flow rate. It is to be appreciated that a tantalum pentaoxide film doped with titanium atoms exhibits a higher dielectric constant than an undoped tantalum pentaoxide film.

In another embodiment of the present invention dielectric layer 208 is a composite dielectric layer comprising a stack of different dielectric materials such as a Ta₂O₅/TiO₂/Ta₂O₅ stack. A Ta₂O₅/TiO₂/Ta₂O₅composite film can be formed by first depositing a tantalum pentaoxide film as described above. After depositing a tantalum pentaoxide film having a thickness between 20-50 Å the flow of the tantalum source is stopped and replaced with a flow of a source of titanium, such as TIPT, at a diluted flow rate of between 5-20 mg/min. After depositing a titanium oxide film having a thickness of between 20-50 Å, the titanium source is replaced with the tantalum source and the deposition continued to form a second tantalum pentaoxide film having a thickness of between 20-50 Å. By sandwiching a higher dielectric constant titanium oxide (TiO₂) film between two tantalum pentaoxide (Ta₂O₅) films, the dielectric constant of a composite stack is increased over that of a homogeneous layer of tantalum pentaoxide (Ta₂O₅).

Next, as set forth in block 108 of flow chart 100, dielectric film 208 is annealed with remotely generated active atomic species 211 as shown in FIG. 2d, to form an annealed dielectric layer 210. Dielectric film 208 can be annealed by placing substrate 200 into anneal chamber 350 coupled to remote plasma generator 301. Substrate 200 is then heated to an anneal temperature and exposed to active atomic species 211 generated by disassociating an anneal gas in applicator chamber 310. By generating the active atomic species in a chamber remote from the anneal chamber (the chamber in which the substrate is situated) a low temperature anneal can be accomplished without exposing the substrate to the harmful plasma used to form the active atomic species. With the process and apparatus of the present invention anneal temperatures of less than 400° C. can be used. The use of remotely generated active atomic species to anneal dielectric film 208 enables anneal temperatures of less than or equal to the deposition temperature of the dielectric film to be used.

In one embodiment of the present invention dielectric film 208 is a transition metal dielectric and is annealed with reactive oxygen atoms formed by remotely disassociating O₂ gas. Dielectric layer 208 can be annealed in chamber 350 with a reactive oxygen atoms created by providing an anneal gas comprising two SLM of O₂ and one SLM of N2 into chamber 310, and applying a power between 500-1500 watts to magnatron 302 to generate microwaves which causes a plasma to ignite from the anneal gas. Alternatively, reactive oxygen atoms can be formed by flowing an anneal gas comprising two SLM of O₂ and three SLM of argon (Ar) into cavity 310. While reactive oxygen atoms are fed into anneal chamber 350, substrate 200 is heated to a temperature of approximately 300° C. and chamber 350 maintained at an anneal pressure of approximately 2 Torr. Dielectric layer 208 can be sufficiently annealed by exposing substrate 200 to reactive oxygen atoms for between 30-120 seconds.

An inert gas, such as N₂ or argon (Ar), is preferably included in the anneal gas stream in order to help prevent recombination of the active atomic species. It is to be noted that as the active atomic species (e.g. reactive oxygen atoms) travel from the applicator cavity 310 to the anneal chamber 350, they collide with one another and recombine to form O₂ molecules. By including an inert gas, in the anneal gas mix, the inert gas does not disassociate and so provides atoms which the active atomic species can collide into without recombining. Additionally, in order to help prevent recombination of the active atomic species, it is advisable to keep the distance between cavity 310 and anneal chamber 350 as short as possible.

Annealing a transition-metal dielectric film 208 with reactive atoms oxygen fills oxygen vacancies (satisfies sites) in the dielectric film 208 which greatly reduces the leakage of the film. Additionally, annealing transition metal dielectric 208 helps to remove carbon (C) in the film which can contribute to leakage. Carbon can be incorporated into transition metal dielectrics because the tantalum and titanium sources, TAT-DMAE, TAETO, and TIPT are carbon containing compounds. The reactive oxygen atoms remove carbon from the film by reacting with carbon and forming carbon dioxide (CO₂) vapor which can then be exhausted out from the chamber.

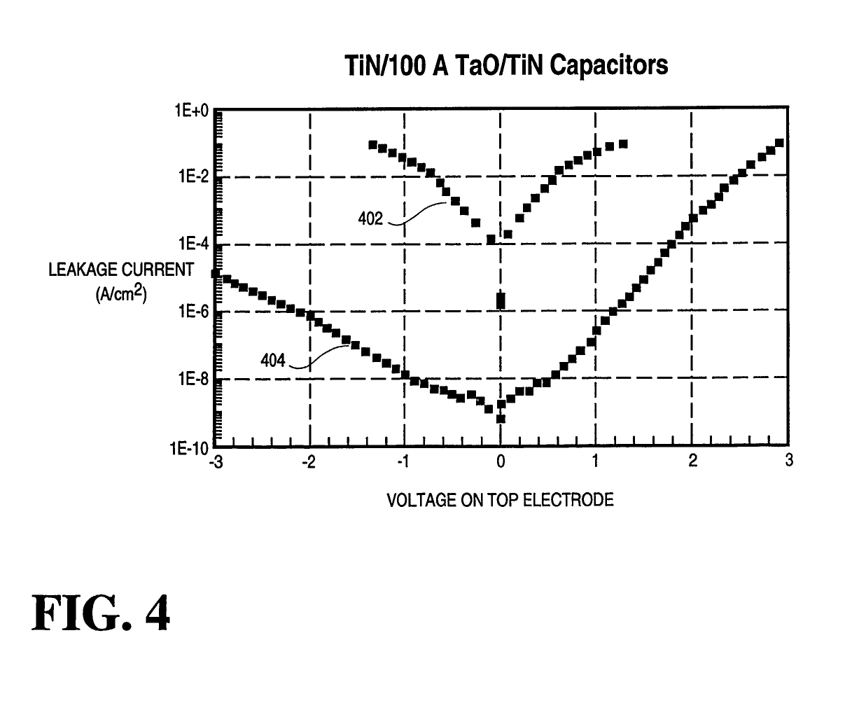

FIG. 4 illustrates how exposing a tantalum pentaoxide dielectric film to remotely generated reactive oxygen atoms improves the quality and electrical performance of the as deposited film. Graph 402 shows how the leakage current of a capacitor having a 100 Å unannealed tantalum pentaoxide dielectric film varies for different top electrode voltages. Graph 404 shows how the leakage current of a capacitor having a 100 Å tantalum pentaoxide dielectric film annealed with remotely generated reactive oxygen atoms varies for different top electrode voltages. As can be seen from graph 402, a capacitor utilizing an unannealed tantalum pentaoxide dielectric experiences high leakage current of about 1×10⁻¹ (amps/cm²) when ±1.5 volts is applied to the top electrode and a high leakage current of 1×10⁻⁶ (amps/cm²) when zero volts is applied to the top electrode. In comparison, when the tantalum pentaoxide dielectric is exposed to remotely generated reactive oxygen atoms, the leakage current has a relatively low leakage current of 1×10⁻⁵ (amps/cm²) when ±1.5 volts is applied to the top electrode and a leakage current of less than 1×10⁻⁹ (amps/cm²) when zero volts is applied to the top electrode. As is readily apparent from FIG. 4, exposing the tantalum pentaoxide dielectric film to remotely generated active oxygen atoms dramatically improves (reduces) the leakage current of the film.

In an embodiment of the present invention, as set forth in block 107 of flow chart 100 the deposition step 106 and the anneal step 108 occur simultaneously so that the dielectric film is annealed as it is deposited. A dielectric film can be deposited and annealed simultaneously using a single deposition/anneal chamber coupled to receive a remote plasma from a remote plasma generator source and coupled to receive a deposition gas mix. For example in one embodiment of the present invention a deposition gas mix comprising a metal source such as a TAT-DMAE or TIPT, or a silicon source, such as TEOS, and a source of oxygen such as O₂ or N₂O can be fed into a common anneal/deposition chamber while the substrate is heated to a desired deposition temperature and the chamber maintained at a desired deposition pressure. Simultaneously, an anneal gas, such as O₂, can be supplied into applicator cavity chamber 310 of the remote plasma generator 300 at a rate of between 0.5-2 SLM. Reactive oxygen atoms can then flow from chamber 310 into the anneal/deposition chamber. The reactive oxygen atoms then react with the metal or silicon provided from the deposition gas mix to form a metal-oxide or silicon-oxide compound respectively. In one embodiment of the present invention the only source of oxygen atoms into the deposition/anneal chamber is reactive oxygen atoms from applicator 310.

The next step of the present invention, as set forth in block 110 of flow chart 100 is to complete the processing of the device. For example, as shown in FIG. 2e, a top capacitor electrode 212 can be formed over annealed dielectric layer 210. Any well known technology can be used to form top electrode 212 including blanket depositing a polysilicon film or metal film, such as TiN, over annealed dielectric film 210 and then using well known photolithography and etching techniques to pattern the electrode film and dielectric layer.

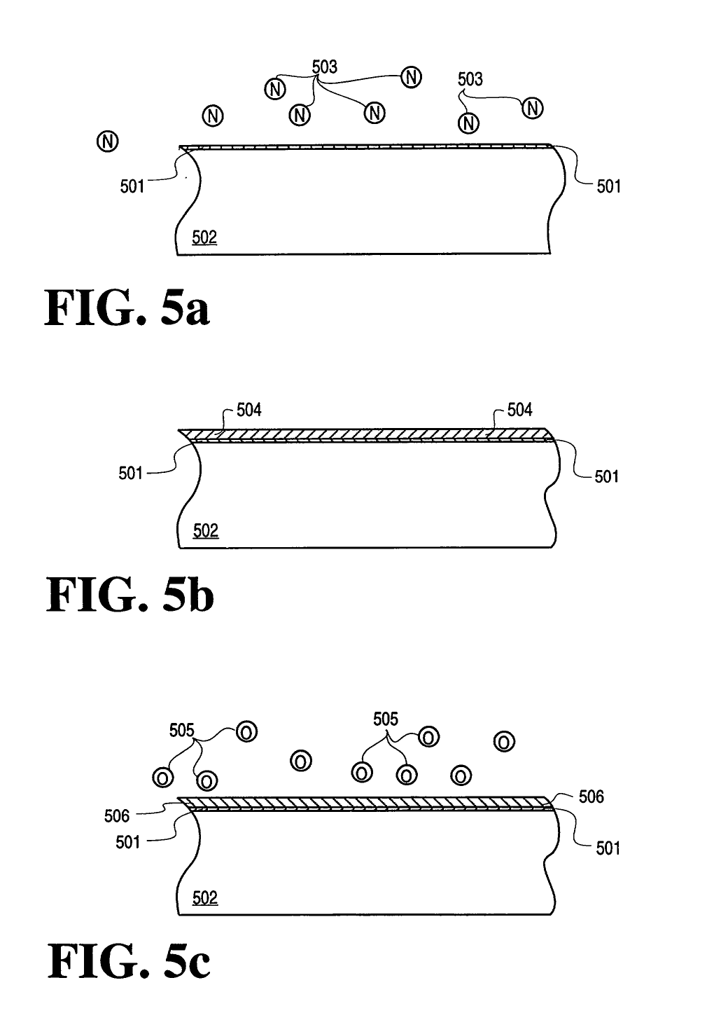

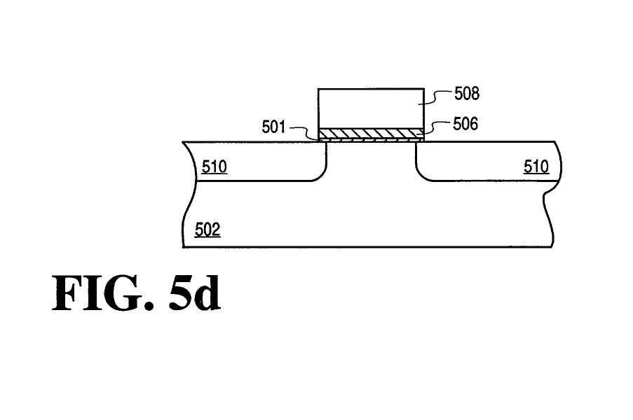

In another embodiment of the present invention, remotely generated active atomic species can be used to fabricate a metal oxide semiconductor (MOS) transistor. The first step, as shown in FIG. 5a, which is optional, is to nitridate a monocrystalline silicon substrate 502 with remotely generated reactive nitrogen atoms 503 as describe above. Nitridating substrate 502 with remotely generated reactive nitrogen atom forms a thin silicon nitride film 501 on substrate 502 which improves the interface between the silicon substrate 502 and the subsequently deposited gate dielectric layer. Next, as shown in FIG. 5b a gate dielectric layer 504 is formed over nitridated substrate 502. Gate dielectric layer 504 can be a thermally grown silicon dioxide film, a CVD deposited silicon dioxide film, or a transition metal film such as tantalum pentaoxide or titanium oxide or combinations thereof. Gate dielectric 504 will typically have a thickness between 20 to 100 Å. Next, as shown in FIG. 5c, the dielectric film 504 is annealed with remotely generated active atomic species 505, such as reactive oxygen atoms, to form an annealed dielectric film 506 as described above. Annealing of the gate dielectric film fills vacancies in the lattice and generally improves the quality of the film. The annealing step can occur as a separate step after the deposition of the gate dielectric or can occur simultaneous with the deposition of the gate dielectric. After forming annealed gate dielectric 506, a gate electrode material, such as polysilicon or a metal or a combination thereof, can be blanket deposited over annealed gate dielectric 506 and then patterned into a gate electrode 508, as shown in FIG. 5d, with well known photolithography and etching techniques. A pair of source/drain regions 510 can then be formed on opposite sides of the gate electrode 508 with well known ion implantation or solid source diffusion techniques, in order to complete fabrication of the MOS device.

A novel method and apparatus for forming and/or annealing a dielectric film with a remotely generated active atomic species has been described. Utilizing a, remotely generated active atomic species to anneal and/or deposit a film enables a high quality, high dielectric constant film to be formed at low temperatures. Although the present invention has been described with respect to specific equipment, and with respect to a specific processes it is to be appreciated that the described details are to be taken as illustrative rather than limiting, wherein the scope of the present invention is to be measured by the appended claims which follow.

Thus, a method and apparatus for annealing a dielectric film at low temperatures has been described.

We claim:

1. A method of annealing a dielectric layer, said method comprising the steps of:
forming a dielectric layer on a substrate;
generating an active atomic species in a first chamber; and
exposing said dielectric layer to said active atomic species wherein said substrate is located in a second chamber separate from said first chamber while exposing said dielectric layer to said active atomic species.

2. The method of claim 1 wherein said active atomic species comprises reactive oxygen atoms.

3. The method of claim 1 wherein said active atomic species comprises reactive nitrogen atoms.

4. The method of claim 1 wherein said dielectric layer comprises a metal-oxide.

5. The method of claim 1 wherein said dielectric layer comprises a transition metal dielectric.

6. The method of claim 5 wherein said dielectric layer comprises tantalum pentaoxide (Ta₂O₅).

7. The method of claim 1 wherein said dielectric layer is exposed to said active atomic species while being heated to a temperature of less than 400° C.

8. A method of forming a dielectric layer comprising:
generating an active atomic species in a first chamber; and
depositing a dielectric layer onto a substrate by chemical vapor deposition in a second chamber and while depositing said dielectric layer, providing said active atomic species into said second chamber.

9. The method of claim 8 wherein said active atomic species comprises oxygen radicals.

10. The method of claim 8 wherein said dielectric layer a metal oxide dielectric.

11. The method of claim 8 wherein said dielectric layer comprises a transition metal dielectric.

12. The method of claim 11 wherein said dielectric layer comprises tantalum pentaoxide (Ta₂O₅).

13. The method of claim 8 wherein said dielectric layer comprises a silicon-oxide.

14. A method of annealing a deposited oxide, said method comprising the steps of:
locating a substrate in a first chamber, said substrate having a deposited oxide formed thereon;
generating reactive oxygen atoms in a second chamber; and
transporting said reactive oxygen atoms from said second chamber into said first chamber and exposing said deposited oxide to said reactive oxygen atoms.

15. The method of claim 14 wherein said deposited oxide is exposed to said reactive oxygen atoms while heating said substrate to at a temperature of less than 400° C.

16. The method of claim 14 wherein said second chamber is a microwave applicator cavity of a remote plasma generator.

17. The method of claim 14 wherein said reactive oxygen atoms are formed by generating a plasma from O₂ molecules.

18. The method of claim 14 wherein said reactive oxygen atoms are formed by generating a plasma from N₂O molecules.

19. The method of claim 14 wherein said reactive oxygen atoms are formed by generating a plasma from O₂ molecules utilizing microwaves.

20. The method of claim 14 wherein said deposited oxide is a silicon-oxide.

21. The method of claim 14 wherein said deposited oxide is a metal-oxide.

22. The method of claim 21 wherein said deposited metal oxide is a transition metal oxide.

23. The method of claim 22 wherein said transition metal-oxide is tantalum pentaoxide (Ta₂O₅).

24. A method of forming a capacitor, said method comprising the steps of:
forming a bottom electrode;
depositing a transition metal dielectric on said bottom electrode in a deposition chamber;
generating reactive oxygen atoms by forming a plasma from an oxygen containing gas in a microwave applicator cavity in a remote plasma generation chamber;
annealing said transition metal dielectric by exposing said transition metal dielectric to said reactive oxygen atoms, wherein said annealing step occurs in a chamber separate from said microwave applicator cavity; and
forming a top electrode on said reactive oxygen atom exposed transition metal dielectric.

25. The method of claim 24 wherein said transition metal dielectric is tantalum pentaoxide (Ta₂O₅) deposited by chemical vapor deposition utilizing a source gas comprising TAETO.

26. The method of claim 24 wherein said transition metal dielectric is tantalum pentaoxide (Ta₂O₅) formed by chemical vapor deposition utilizing a source gas comprising TAT-DMAE.

27. The method of claim 25 wherein said tantalum pentaoxide dielectric layer is formed utilizing a source gas comprising O₂.

28. The method of claim 24 wherein said transition metal dielectric layer is deposited at a temperature between 300-500° C.

29. The method of claim 24 wherein said transition metal dielectric is formed with a source gas comprising N₂O.

30. The method of claim 24 wherein said transition metal dielectric is annealed in the deposition chamber.

31. The method of claim 24 wherein said transition metal dielectric film is annealed at a temperature less than 400° C.

32. The method of claim 24 wherein said transition metal dielectric is annealed in a chamber different than the deposition chamber in which said transition metal dielectric was deposited.

33. A method of forming a dielectric film, said method comprising the steps of:
placing a substrate in the deposition chamber;
heating said substrate to a deposition temperature;
providing a metal source into said chamber;
thermally decomposing said metal source to provide metal atoms;
generating reactive oxygen atoms in a second chamber;
providing said reactive oxygen atoms into said deposition chamber; and
forming a dielectric film on said substrate by combining said metal atoms with said reactive oxygen atoms.

34. The method of claim 33 wherein no other source of oxygen is provided into said deposition chamber other then said reactive oxygen atoms during said formation of said dielectric film.

35. The method of claim 33 wherein said reactive oxygen atoms are formed from a plasma formed by applying microwaves to oxygen gas (O₂).

36. The method of claim 33 wherein said reactive oxygen atoms are formed from a plasma created by applying microwaves to N₂O molecules.

37. A method of passivating a silicon nitride film, said method comprising the steps of:
locating a substrate in a first chamber, said substrate having a silicon nitride layer formed thereon;
generating reactive nitrogen atoms in a second chamber; and
transporting said reactive nitrogen atoms from said second chamber into said first chamber and exposing said silicon nitride film to said reactive oxygen atoms.

38. The method of claim 37 wherein said reactive nitrogen atoms are formed from an anneal gas comprising N₂.

39. The method of claim 38 wherein said reactive nitrogen atoms are formed from an anneal gas comprising N₂ and H₂.

40. A method of forming a silicon nitride film on a substrate, said method comprising the step of:
locating a substrate in a first chamber, said substrate having a silicon surface;
generating active nitrogen atoms in a second chamber; and
transporting said reactive nitrogen atoms from said second chamber into said first chamber and reacting said silicon surface with said reactive nitrogen atoms to form a silicon nitride film on said substrate.

41. The method of claim 40 wherein said reactive nitrogen atoms are formed from an annealed gas comprising N₂.

42. The method of claim 40 wherein said reactive nitrogen atoms are formed from an annealed gas comprising ammonia (NH₃).

43. A method of forming a tantalum pentaoxide dielectric film, said method comprising the steps of:
placing a substrate into a deposition chamber;
providing a metal organic tantalum containing precursor into said chamber;
providing nitrous oxide (N₂O) into said chamber;
thermally decomposing said metal organic tantalum containing precursor in said chamber to provide tantalum atoms; and
reacting said tantalum atoms with said nitrous oxide (N₂O) to form a tantalum pentaoxide (Ta₂O₅) dielectric film on said substrate.

44. The method of claim 43 further comprising the step of heating said substrate to a temperature between 300-500° C. while providing said metal organic tantalum precursor and said nitrous oxide (N₂O) into said chamber.

45. The method of claim 43 wherein said metal organic tantalum containing precursor is selected from the group consisting of TAT-DMAE and TAETO.
